(19) United States
(12) Patent Application Publication
(10) Pub. No.: US 2026/0150333 A1
(43) Pub. Date: May 28, 2026

(54) SEMICONDUCTOR DEVICE

(71) Applicant: Samsung Electronics Co., Ltd., Suwon-si (KR)

(72) Inventors: Dawon JEONG, Suwon-si (KR); Junhyeok KIM, Suwon-si (KR); Yonghee PARK, Suwon-si (KR); Jae-Hyun YOO, Suwon-si (KR); Jongwoon YOON, Suwon-si (KR); Kyuyeop LEE, Suwon-si (KR)

(73) Assignee: Samsung Electronics Co., Ltd., Suwon-si (KR)

(21) Appl. No.: 19/231,642

(22) Filed: Jun. 9, 2025

(30) Foreign Application Priority Data
Nov. 22, 2024 (KR) 10-2024-0168690

(51) Int. Cl. H10D 30/65; H10D 30/01; H10D 62/00; H10D 62/10; H10D 62/17

(52) U.S. Cl. CPC H10D 30/65; H10D 30/0281; H10D 62/054; H10D 62/109; H10D 62/393

(57) ABSTRACT

A semiconductor device including a semiconductor substrate having upper and lower areas, the lower area including a lower layer having a first conductivity type; a first deep well region having the first conductivity type and being on the upper area; a connection layer having the first conductivity type and being on the first deep well region; a body region having the first conductivity type and a first drift region having a second conductivity type, the body region and the first drift region being side-by-side in a first direction on the connection layer; a first source region having the second conductivity type and being on the body region; a drain region having the second conductivity type and being on the upper area and spaced apart from the first drift region in the first direction; and a gate structure on the first drift region and being adjacent to the first source region.

### CROSS-REFERENCE TO RELATED APPLICATION

This application claims priority under 35 U.S. C § 119 to Korean Patent Application No. 10-2024-0168690 filed on Nov. 22, 2024, in the Korean Intellectual Property Office, the disclosure of which is hereby incorporated by reference in its entirety.

### BACKGROUND

The present inventive concepts relate to semiconductor devices, and more particularly, to semiconductor devices having a lateral diffused metal oxide semiconductor (LDMOS) structure.

As an ordinary power metal oxide semiconductor field effect transistor (MOSFET) has high input impedance compared to a bipolar transistor, the power MOSFET may have high power gain and simple gate driving circuits, and as the power MOSFET is a unipolar device, the power MOSFET may have an advantage of no time delay caused by accumulation or recombination of minority carrier while being turned-off. Thus, the power MOSFET is gradually increasingly applied to various applications such as switching mode power supply devices, lamp stabilization, and/or motor driving circuits. A double diffused MOSFET structure utilizing planar diffusion technology is widely used as the power MOSFET, and a lateral double diffused MOSFET (LDMOSFET) is representative thereof.

### SUMMARY

Some example embodiments of the present inventive concepts provide a semiconductor device with improved electrical properties.

The objects of the present inventive concepts are not limited to the above mentioned, and other objects which have not been mentioned above will be clearly understood to those skilled in the art from the following description.

Some example embodiments of the present inventive concepts provide a semiconductor device that includes a semiconductor substrate including an upper area and a lower area, the lower area including a lower layer having a first conductivity type; a first deep well region having the first conductivity type, the first deep well region being on the upper area; a connection layer having the first conductivity type, the connection layer being on the first deep well region; a body region having the first conductivity type and a first drift region having a second conductivity type different than the first conductivity type, the body region and the first drift region being side-by-side in a first direction on the connection layer; a first source region having the second conductivity type, the first source region being on the body region; a drain region having the second conductivity type, the drain region being on the upper area and being spaced apart from the first drift region in the first direction; and a gate structure on the first drift region, the gate structure being adjacent to the first source region.

Some example embodiments of the present inventive concepts still further provide a semiconductor device that includes a semiconductor substrate including an upper area and a lower area, the lower area including a lower layer having a first conductivity type; a buried layer having a second conductivity type different than the first conductivity type, the buried layer being on the lower layer; an epitaxial layer having the first conductivity type, the epitaxial layer being on the upper area; a first deep well region having the first conductivity type, the first deep well region being on the epitaxial layer; a second deep well region having the second conductivity type, the second deep well region being side-by-side with the first deep well region in a first direction, and the second deep well region having a bottom end in contact with the buried layer; a connection layer having the first conductivity type, the connection layer being on the first deep well region; a body region having the first conductivity type and a first drift region having the second conductivity type, the body region and the first drift region being side-by-side in the first direction on the connection layer; a first source region having the second conductivity type, the first source region being on the body region; a second drift region having the second conductivity type, the second drift region being on the second deep well region and contacting lateral portions of the first drift region and the connection layer; a first shallow well region in the second drift region, the first shallow well region being spaced apart from the first drift region; a drain region having the second conductivity type, the drain region being on the first shallow well region; a gate structure on the first drift region, the gate structure being adjacent to the first source region; and a local oxidation layer between the first drift region and a portion of the gate structure. A portion of the local oxidation layer is in the first drift region. The local oxidation layer is between the drain region and the body region, and the local oxidation layer is spaced apart from the body region. The connection layer has a first thickness. The first drift region has a second thickness from a bottom end of the first drift region to a bottom surface of the local oxidation layer. The second thickness is greater than the first thickness.

Some example embodiments of the present inventive concepts still further provide a semiconductor device that includes a semiconductor substrate including an upper area and a lower area, the lower area including a lower layer having a first conductivity type; a first deep well region having the first conductivity type and a second deep well region having a second conductivity type different than the first conductivity type, the first deep well region and the second deep well region being side-by-side in a first direction on the upper area; a body region having the first conductivity type and a first drift region having the second conductivity type, the body region and the first drift region being side-by-side in the first direction on the first deep well region; a first source region having the second conductivity type, the first source region being on the body region; a gate structure on the first drift region, the gate structure being adjacent to the first source region; a first shallow well region having the second conductivity type, the first shallow well region being on the second deep well region; and a drain region having the second conductivity type, the drain region being on the first shallow well region and being spaced apart from the first drift region in the first direction. The first drift region includes a first region adjacent to the gate structure, and a concentration of a dopant of the second conductivity type in the first drift region increases in a direction toward the first region from a bottom end of the first drift region.

Some example embodiments of the present inventive concepts provide a manufacturing method of a semiconductor device that includes providing a semiconductor substrate including an upper area and a lower area, the lower area including a lower layer having a first conductivity type; forming a first deep well region on the upper area, the first deep well region having the first conductivity type; forming a connection layer on the first deep well region, the connection layer having the first conductivity type; forming a body region and a first drift region on the connection layer side-by-side along a first direction, the body region having the first conductivity type and the first drift region having a second conductivity type different than the first conductivity type; forming a first source region on the body region, the first source region having the second conductivity type; forming a drain region on the upper area, the drain region having the second conductivity type and being spaced apart from the first drift region in the first direction; and forming a gate structure on the first drift region, the gate structure being adjacent to the first source region.

In some example embodiments, the method of manufacturing the semiconductor device further includes forming a second deep well region on the upper area, the second deep well region having the second conductivity type and being side-by-side with the first deep well region in the first direction; and forming a first shallow well region on the second deep well region, the first shallow well region having the second conductivity type and being adjacent to lateral portions of the first drift region and the connection layer, wherein the drain region is on an upper portion of the first shallow well region.

In some example embodiments, the method of manufacturing the semiconductor device further includes forming a second drift region on the second deep well region, the second drift region having the second conductivity type, and covering a lower portion and a lateral portion of the first shallow well region, the second drift region being in contact with the lateral portions of the first drift region and the connection layer, wherein a first horizontal distance between the first shallow well region and the first deep well region is greater than a second horizontal distance between the first shallow well region and the first drift region.

In some example embodiments, the forming the second deep well region includes forming a first sub-well region and a second sub-well region stacked on the first sub-well region.

In some example embodiments, the first and second sub-well regions are doped with an n-type dopant, and a concentration of the n-type dopant in the first sub-well region is different from a concentration of the n-type dopant in the second sub-well region.

In some example embodiments, the method of manufacturing the semiconductor device further includes forming a local oxidation layer between the first drift region and a portion of the gate structure, wherein a portion of the local oxidation layer is in the first drift region, and wherein the local oxidation layer is between the drain region and the body region and is spaced apart from the body region.

In some example embodiments, the method of manufacturing the semiconductor device further includes forming a second source region on the body region, the second source region having the first conductivity type and being adjacent to the first source region.

In some example embodiments, the method of manufacturing the semiconductor device further includes forming a buried layer on the lower area, the buried layer having the second conductivity type, wherein the buried layer contacts a bottom end of the second deep well region and is spaced apart from a bottom end of the first deep well region.

In some example embodiments, the method of manufacturing the semiconductor device further includes forming a device isolation layer that penetrates the first shallow well region, the second deep well region, and a portion of the lower layer.

### BRIEF DESCRIPTION OF DRAWINGS

FIG. 1A illustrates a plan view showing a semiconductor device according to some example embodiments of the present inventive concepts.

FIG. 1B illustrates a cross-sectional view taken along line A-A′ of FIG. 1A according to some example embodiments of the present inventive concepts.

FIG. 1C illustrates a perspective view showing a semiconductor device having a cross section of FIG. 1B.

FIG. 1D illustrates a cross-sectional view taken along line A-A′ of FIG. 1A according to some example embodiments of the present inventive concepts.

FIGS. 2A, 2B, 2C, 2D, 2E, 2F, 2G, 2H and 2I illustrate cross-sectional views showing a method of fabricating a semiconductor device having a cross section of FIG. 1B according to some example embodiments of the present inventive concepts.

FIGS. 3, 4, and 5 illustrate cross-sectional views showing a semiconductor device according to some example embodiments of the present inventive concepts.

FIGS. 6 and 7 illustrate cross-sectional views showing a semiconductor device according to some example embodiments of the present inventive concepts.

### DETAILED DESCRIPTION

Some example embodiments of the present inventive concepts will now be described in detail with reference to the accompanying drawings to aid in clearly explaining the present inventive concepts. In this description, such terms as “first” and “second” may be used to simply distinguish identical or similar components from each other, and the sequence of such terms may be changed in accordance with the order of mention.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

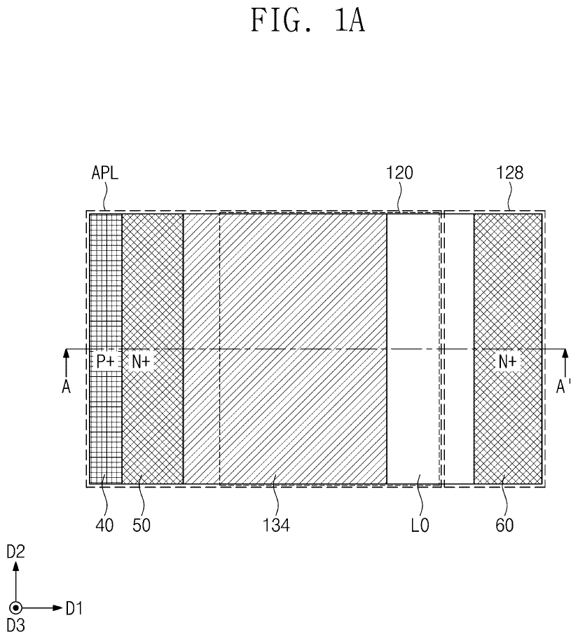

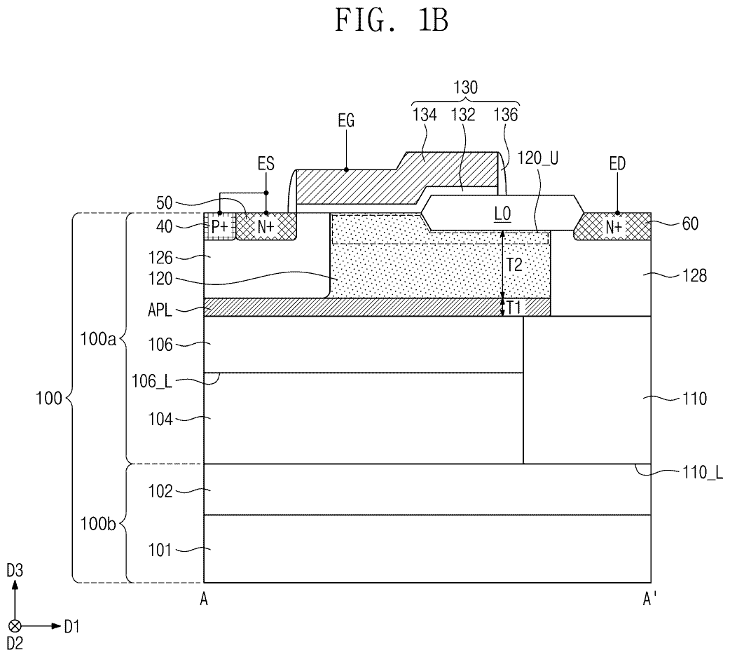

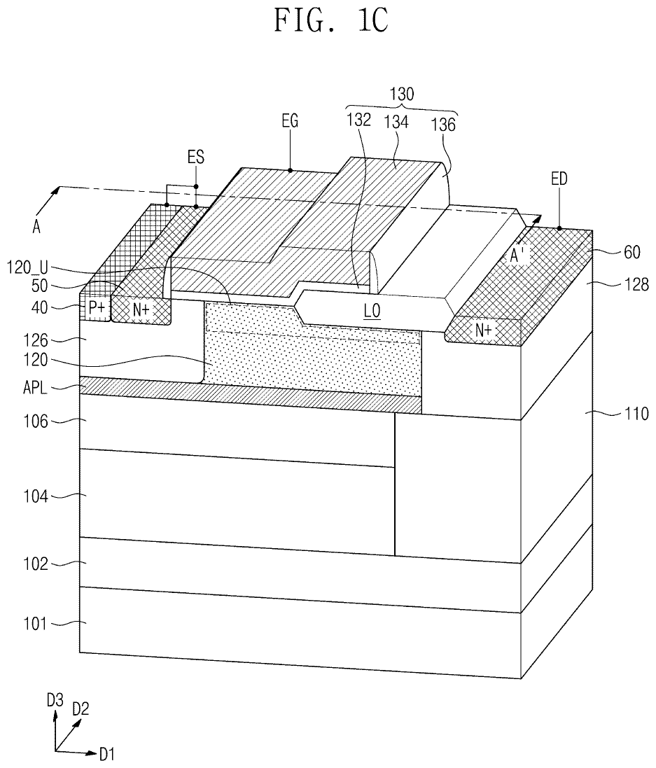

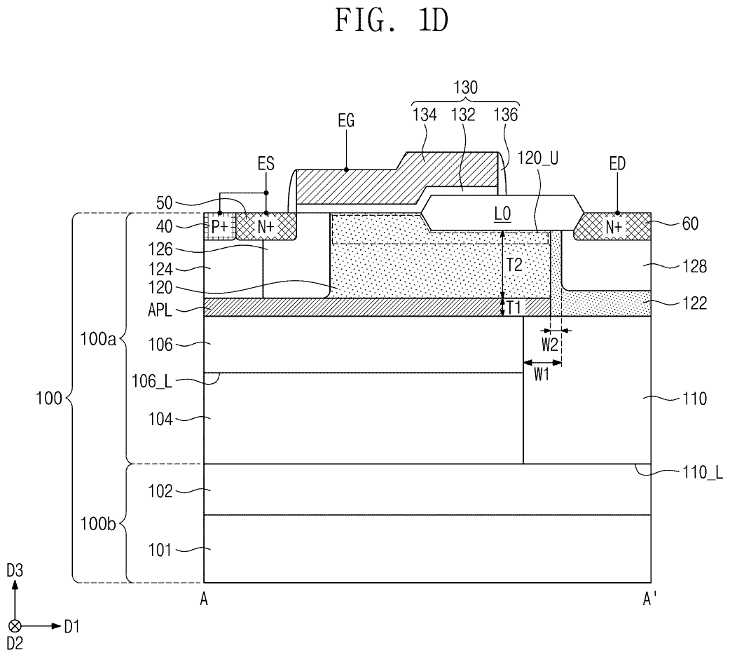

FIG. 1A illustrates a plan view showing a semiconductor device according to some example embodiments of the present inventive concepts. FIG. 1B illustrates a cross-sectional view taken along line A-A′ of FIG. 1A according to some example embodiments of the present inventive concepts. FIG. 1C illustrates a perspective view showing a semiconductor device having a cross section of FIG. 1B. FIG. 1D illustrates a cross-sectional view taken along line A-A′ of FIG. 1A according to some example embodiments of the present inventive concepts.

Referring to FIGS. 1A, 1B, and 1C, a semiconductor device according to some example embodiments may be an n-type lateral diffused metal oxide semiconductor (LDMOS) device. Differently from that shown, the semiconductor device may be a p-type LDMOS device. In the LDMOS device as a power device or a high-voltage device, there may be desirable features, such as a breakdown voltage that blocks current flow in an off-state and a resistance (Rsp: specific on resistance) when a current flows at a switched-on state. These two features may be conflicting trends due to characteristics of a silicon material.

The semiconductor device according to some example embodiments may include a semiconductor substrate 100. The semiconductor substrate 100 may include, for example, a silicon semiconductor substrate, a gallium-arsenic semiconductor substrate, a silicon-germanium semiconductor substrate, a ceramic semiconductor substrate, a quartz semiconductor substrate, or a glass semiconductor substrate. The semiconductor substrate 100 may include a lower layer 101 that may be p-type. In this description, the term “p-type” may be called “first conductivity type”, and the term “n-type” may be called “second conductivity type.” In some example embodiments, a p-type dopant may be boron (B) and an n-type dopant may be phosphorus (P), but the present inventive concepts are not limited thereto.

The semiconductor substrate 100 may include an upper area 100a and a lower area 100b. The upper area 100a may include an epitaxial layer 104, a first deep well region 106, a second deep well region 110, a connection layer APL, a first shallow well region 128, a first drift region 120, a body region 126, a first source region 50, a second source region 40, and a drain region 60. The lower area 100b may include a buried layer 102 and lower layer 101.

The epitaxial layer 104 may be disposed on the upper area 100a of the semiconductor substrate 100. The epitaxial layer 104 may have a thickness of, for example, about 5 μm to about 10.5 μm. The epitaxial layer 104 may be of p-type. For example, a p-type dopant concentration of the epitaxial layer 104 may be the same as a p-type dopant concentration of the lower layer 101. The present inventive concepts, however, are not limited thereto, and the p-type dopant concentration of the epitaxial layer 104 may be greater than the p-type dopant concentration of the lower layer 101. For example, a reduced surface field (RESURF) effect, which is capable of effectively reducing an electric field at surfaces and increasing a concentration of a drift region, may increase a breakdown voltage, while decreasing resistances of the first and second drift regions 120 and 122.

The first deep well region 106 and the second deep well region 110 may be disposed side-by-side in a first direction D1. The buried layer 102 may be in contact with a bottom end 110_L of the second deep well region 110 and spaced apart from a bottom end 106_L of the first deep well region 106. For example, the bottom end 110_L of the second deep well region 110 may be closer than the bottom end 106_L of the first deep well region 106 to the buried layer 102. The first deep well region 106 may be p-type, and the second deep well region 110 may be of n-type.

The connection layer APL may be disposed on the first deep well region 106. The connection layer APL may extend to cover a portion of the second deep well region 110. The connection layer APL may be of p-type. A p-type dopant concentration of the connection layer APL may be different from a p-type dopant concentration of the first deep well region 106.

The body region 126 and the first drift region 120 may be disposed on the connection layer APL. The body region 126 and the first drift region 120 may be disposed side-by-side in the first direction D1 on the connection layer APL. The first drift region 120 and the connection layer APL may extend to overlap the second deep well region 110. The first drift region 120 may be of n-type. The body region 126 may be of p-type.

The connection layer APL may connect the body region 126 and the first deep well region 106 for fear of the separation between the body region 126 and the first deep well region 106, and thus it may be possible to limit and/or prevent a floating phenomenon that occurs when the body region 126 and the first deep well region 106 are separated from each other. There may be a reinforced connection between the first and second source regions 50 and 40, which will be discussed below, and the epitaxial layer 104, and thus the semiconductor device may be provided with improved electrical properties.

The first shallow well region 128 may be disposed side-by-side in the first direction D1 with the first drift region 120, and may be in contact with a lateral portion of the first drift region 120 and a lateral portion of the connection layer APL. The first shallow well region 128 may be of n-type.

The first source region 50 may be disposed on an upper portion of the body region 126. The first source region 50 may be of n⁺-type. The first source region 50 may be connected to a source electrode ES.

The second source region 40 may be disposed on the upper portion of the body region 126 and adjacent to the first source region 50. The second source region 40 may be a contact region. The second source region 40 may be of p⁺-type. The second source region 40 may be connected to the source electrode ES. A p-type dopant concentration of the second source region 40 may be greater than the p-type dopant concentration of the first deep well region 106.

The drain region 60 may be disposed on an upper portion of the first shallow well region 128. The drain region 60 may be disposed spaced apart from a gate spacer 136. This may be for increasing a breakdown voltage. The drain region 60 may be of n⁺-type. An n-type dopant concentration of the drain region 60 may be greater than an n-type dopant concentration of the second deep well region 110. Therefore, the semiconductor device may have an increased breakdown voltage. The drain region 60 may be connected to a drain electrode ED.

The buried layer 102 may be disposed on lower layer 101 of the lower area 100b of the semiconductor substrate 100. The buried layer 102 may be of n-type. When a voltage is applied to the drain region 60, the buried layer 102 may serve to substantially increase a punch-through voltage by reducing a width of a depletion region that expands from the body region 126. The buried layer 102 may reduce horizontal and vertical parasitic bipolar junction transistor (BJT) operations that may occur during the operation of the semiconductor device.

A gate structure 130 may be disposed on the first drift region 120. The gate structure 130 may be positioned on the first drift region 120 and adjacent to the first source region 50. The gate structure 130 may include a gate dielectric layer 132, a gate conductive layer 134 on the gate dielectric layer 132, and a gate spacer 136. The gate spacer 136 may cover sidewalls of the gate dielectric layer 132 and the gate conductive layer 134. The gate structure 130 may be connected to a gate electrode EG.

The gate dielectric layer 132 may include a dielectric material. For example, the gate dielectric layer 132 may include oxide. The gate conductive layer 134 may include a conductive material. For example, the gate conductive layer 134 may include polysilicon or metal. The gate spacer 136 may include a dielectric material. For example, the gate spacer 136 may include oxide.

The first drift region 120 may include a first region 120_U adjacent to the gate structure 130. An n-type dopant concentration in the first drift region 120 may increase in a direction toward the first region 120_U from a bottom end of the first drift region 120.

A local oxidation layer, such as locos (local oxidation of silicon) oxide layer LO may be interposed between the epitaxial layer 104 and a portion of the gate structure 130. A portion of the locos oxide layer LO may be inserted into the first drift region 120 and the first shallow well region 128. The locos oxide layer LO may be disposed between the drain region 60 and the body region 126, and may be spaced apart in the first direction D1 from the body region 126.

The locos oxide layer LO may reduce an electric field between the gate electrode EG and the drain region 60. The placement of the locos oxide layer LO may lead to a reduction in current path between the drain region 60 and the first and second source regions 50 and 40, thereby reducing (and/or minimizing) a resistance increase caused by the first shallow well region 128.

The connection layer APL may have a first thickness T1. The first drift region 120 may have a second thickness T2 from the bottom end of the first drift region 120 to a bottom surface of the locos oxide layer LO. The second thickness T2 may be greater than the first thickness T1.

Referring to FIG. 1D, the semiconductor device according to some example embodiments may include a second shallow well region 124 and a second drift region 122.

The second shallow well region 124 may be disposed on the connection layer APL and side-by-side in the first direction D1 with the body region 126. The second shallow well region 124 may be of p-type.

The second drift region 122 may be disposed on the second deep well region 110, and may be in contact with the lateral portion of the first drift region 120 and the lateral portion of the connection layer APL. The second drift region 122 may be of n-type. An n-type dopant concentration of the second drift region 122 may be greater than the n-type dopant concentration of the first drift region 120. Thus, the second drift region 122 may allow the semiconductor device to have a high breakdown voltage at high voltages (e.g., 100 V or higher), and there may be a reinforced connection between the buried layer 102, the second deep well region 110, and the drain region 60. Accordingly, the semiconductor device may have improved electrical properties.

The first shallow well region 128 may be disposed in the second drift region 122 and spaced apart from the first drift region 120. The first shallow well region 128 may be of n-type.

When viewed in the first direction D1, a first horizontal distance W1 between the first shallow well region 128 and the first deep well region 106 may be greater than a second horizontal distance W2 between the first shallow well region 128 and the first drift region 120.

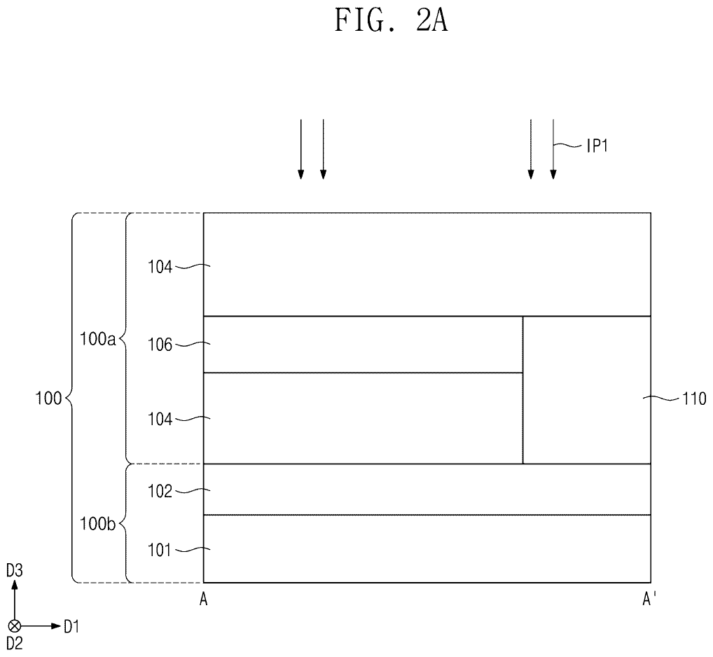

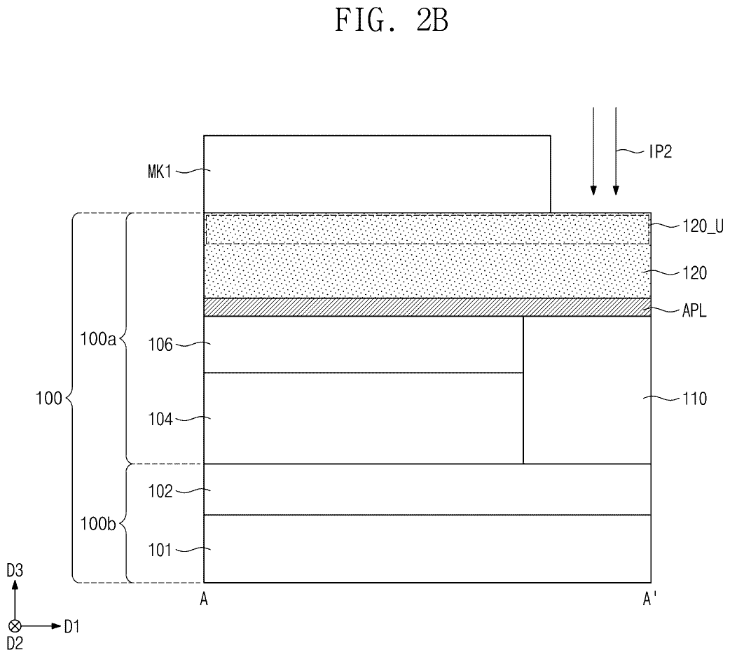

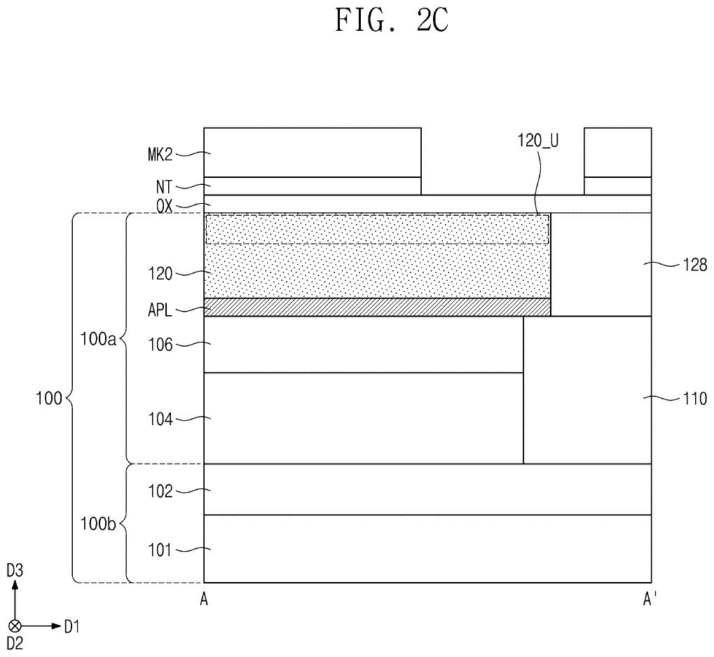

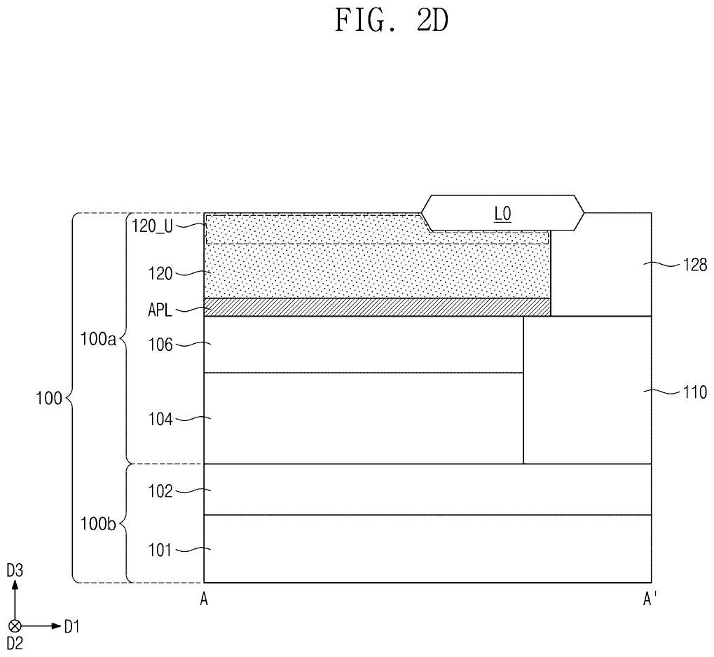

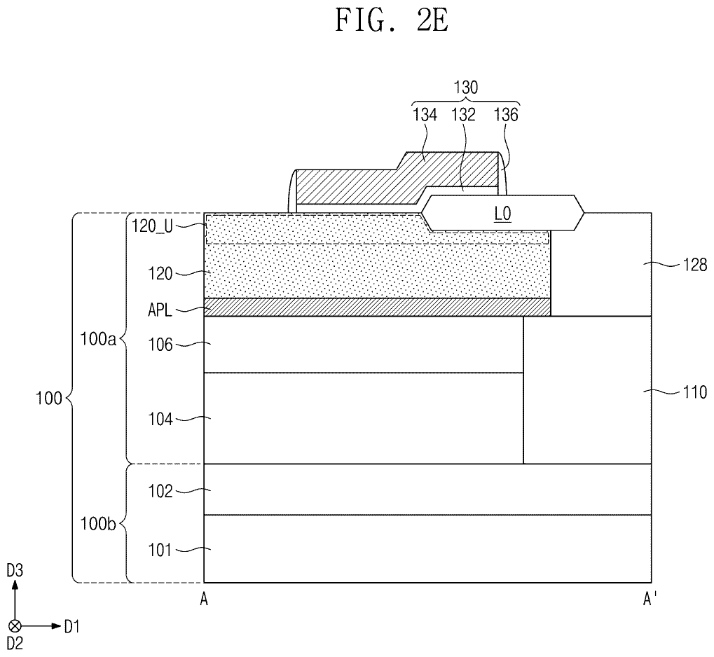

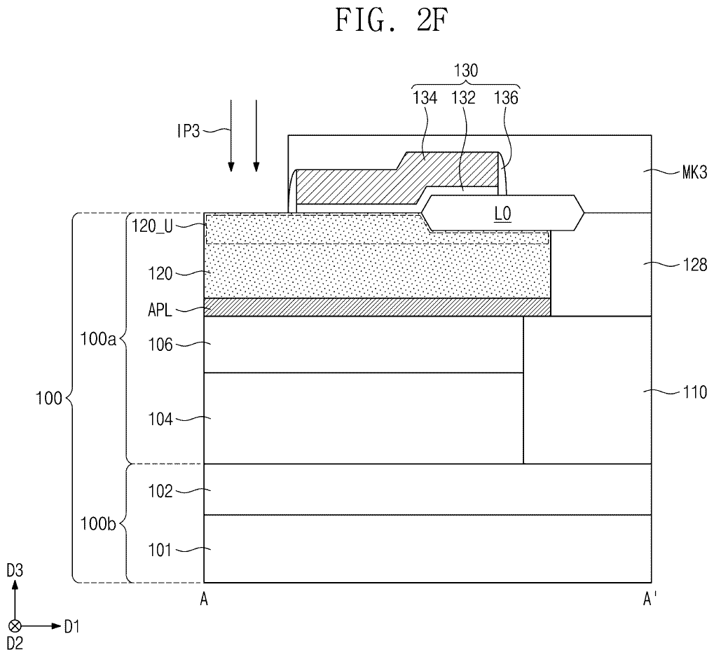

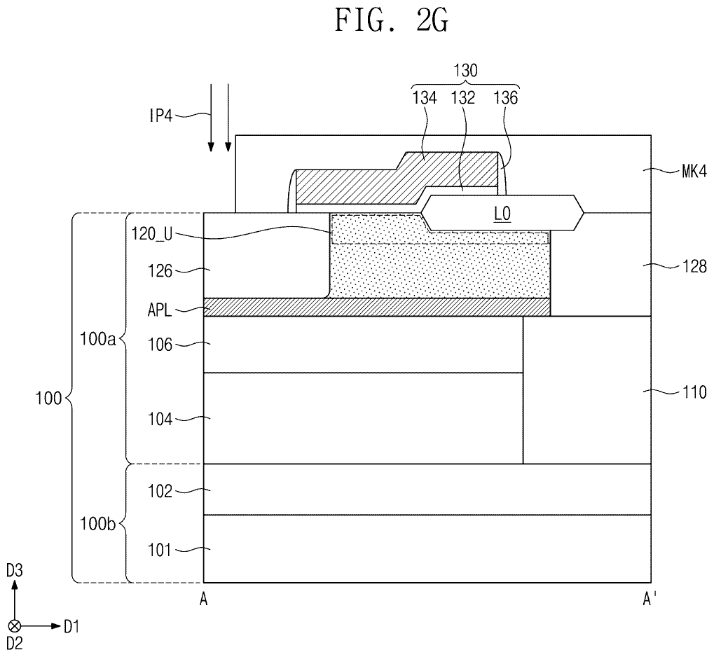

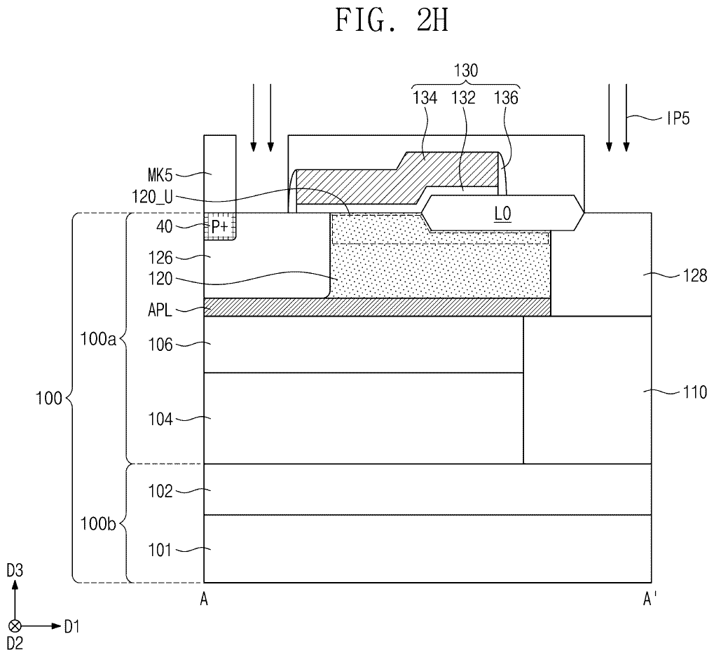

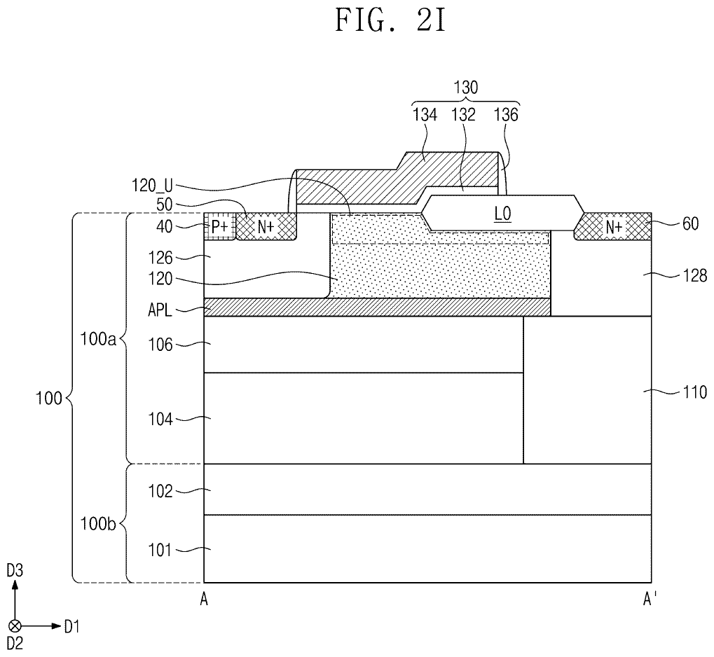

FIGS. 2A to 2I illustrate cross-sectional views showing a method of fabricating a semiconductor device having a cross section of FIG. 1B according to some example embodiments of the present inventive concepts.

Referring to FIG. 2A, a heavily doped n-type buried layer 102 may be formed on p-type lower layer 101 of semiconductor substrate 100 by implanting n-type dopants. The n-type dopants may include phosphorus (P). After that, an epitaxial layer 104 may be formed on a lower substrate (corresponding to a lower area 100b of the semiconductor substrate 100). For example, the epitaxial layer 104 may be formed using selective epitaxial growth (SEG) or solid phase epitaxial growth (SPE). The lower substrate and the epitaxial layer 104 may constitute the semiconductor substrate 100. The lower substrate may be called the lower area 100b of the semiconductor substrate 100. The epitaxial layer 104 may correspond to an upper area 100a of the semiconductor substrate 100.

The epitaxial layer 104 may be implanted with dopants having a first conductivity type to form a first deep well region 106 of the first conductivity type. Then, the epitaxial layer 104 may be implanted with dopants having a second conductivity type to form a second deep well region 110 of the second conductivity type adjacent to the first deep well region 106.

Referring to FIGS. 2A and 2B, a first ion implantation process IP1 may be performed such that the epitaxial layer 104 is implanted with dopants having the second conductivity type to form a first drift region 120 of the second conductivity type. The first drift region 120 may cover an entirety of the lower area 100b of the semiconductor substrate 100. Since the first drift region 120 covers an entirety of the lower area 100b of the semiconductor substrate 100, no mask pattern may be needed when the first ion implantation process IP1 is performed. It may thus be possible to cut manufacturing costs of the semiconductor device. The first ion implantation process IP1 may thereafter implant the first drift region 120 with dopants having the first conductivity type to form a connection layer APL of the first conductivity type. Alternatively, the formation of the connection layer APL may be followed by the formation of the first drift region 120.

Referring to FIGS. 2B and 2C, a second ion implantation process IP2 using a first mask pattern MK1 may be performed such that dopants having the second conductivity type may be implanted to form a first shallow well region 128 of the second conductivity type. The first shallow well region 128 may be in contact with a lateral portion of the first drift region 120 and a lateral portion of the connection layer APL.

Referring to FIGS. 2C and 2D, a buffer oxide layer OX may be formed on the first drift region 120 and the first shallow well region 128. Low pressure chemical vapor deposition (LPCVD) may be performed to form a nitride layer NT on the buffer oxide layer OX. A dry etching using a second mask pattern MK2 may be performed to remove the nitride layer NT, the second mask pattern MK2 may be removed, and then a heat treatment process may be performed to form a locos oxide layer LO.

Referring to FIG. 2E, a gate dielectric layer 132, a gate conductive layer 134, and a gate spacer 136 may be sequentially formed to obtain a gate structure 130.

Referring to FIGS. 2F and 2G, a third ion implantation process IP3 using a third mask pattern MK3 may be performed to implant the first drift region 120 with dopants having the first conductivity type, and a thermal process may be performed to form a body region 126 of the first conductivity type. The thermal process may cause the body region 126 to reach a surface of an upper portion of the semiconductor substrate 100.

Referring to FIGS. 2G and 2H, a fourth ion implantation process IP4 using a fourth mask pattern MK4 may be performed to implant the body region 126 with dopants having the first conductivity type to form a p⁺-type second source region 40.

Referring to FIGS. 2H and 2I, a fifth ion implantation process IP5 using a fifth mask pattern MK5 may be performed to implant the body region 126 with dopants having the second conductivity type to form an n⁺-type first source region 50. The first shallow well region 128 may be implanted with dopants having the second conductivity type to form an n⁺-type drain region 60. Thereafter, a metal deposition process may be performed to form a source electrode ES, a drain electrode ED, and a gate electrode EG, and thus a semiconductor device of FIG. 1B may be fabricated.

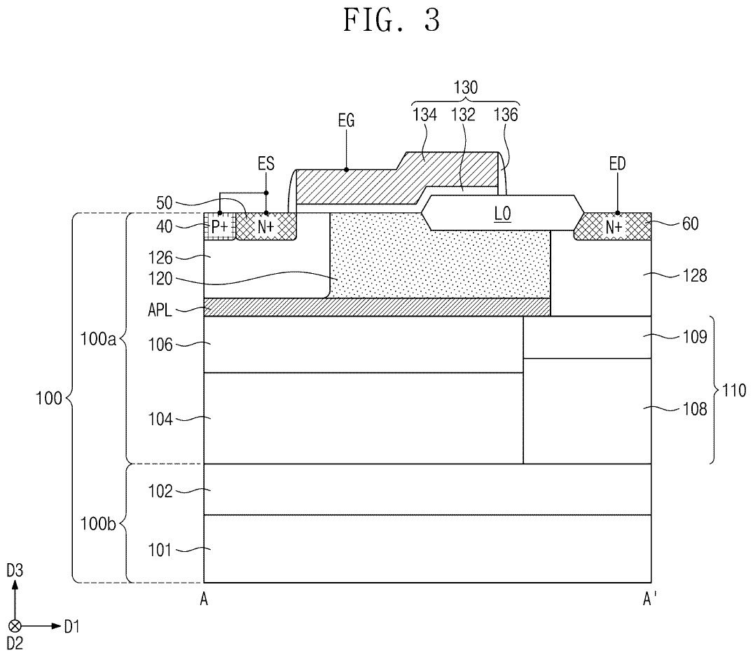

FIGS. 3, 4, and 5 illustrate cross-sectional views showing a semiconductor device according to some example embodiments of the present inventive concepts.

Referring to FIG. 3, in a semiconductor device according to some example embodiments, the second deep well region 110 may include a first sub-well region 108 and a second sub-well region 109 that are sequentially stacked. The first sub-well region 108 and the second sub-well region 109 may be doped with dopants having the second conductivity type, and a concentration of the dopants having the second conductivity type in the first sub-well region 108 may be different from a concentration of the dopants having the second conductivity type in the second sub-well region 109. Other configurations may be identical or similar to those discussed with reference to FIGS. 1A to 2I.

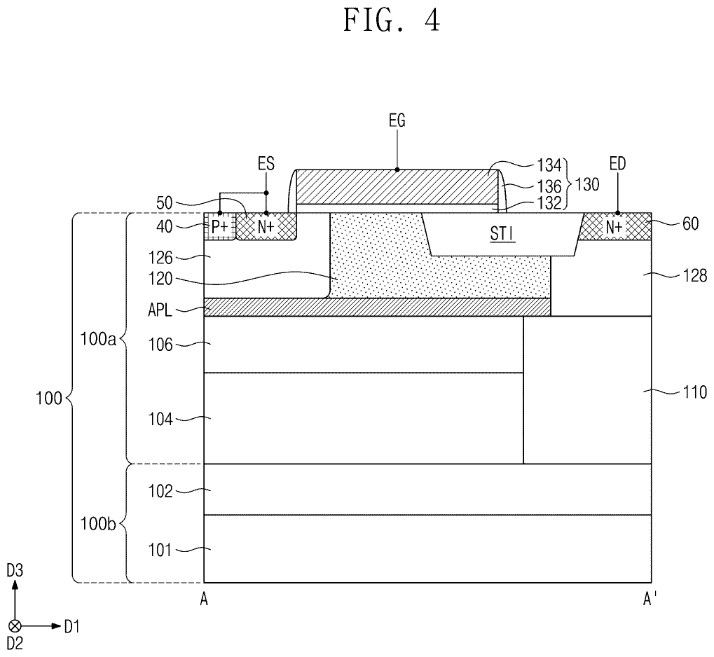

Referring to FIG. 4, in a semiconductor device according to some example embodiments, the locos oxide layer LO may be replaced with a separation pattern STI between the body region 126 and the drain region 60. The separation pattern STI may include, for example, oxide. The separation pattern STI may be formed through a shallow trench isolation process. A reduced surface field (RESURF) effect may be generated by the separation pattern STI formed between the drain region 60 and the first and second source regions 50 and 40, and thus a high electric field across the drain region 60 may decrease with decreasing distance from the first and second source regions 50 and 40. Thus, the semiconductor device may maintain a high breakdown voltage and have improved electrical properties. Other configurations may be identical or similar to those discussed with reference to FIGS. 1A to 2I.

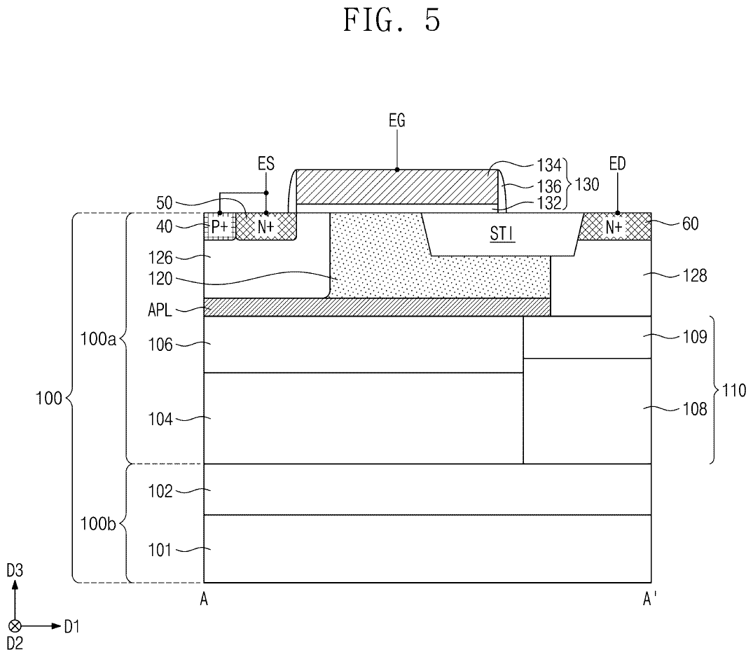

Referring to FIG. 5, in a semiconductor device according to some example embodiments, the second deep well region 110 in the structure of FIG. 4 may include a first sub-well region 108 and a second sub-well region 109 that are sequentially stacked. The first sub-well region 108 and the second sub-well region 109 may be doped with dopants having the second conductivity type, and a concentration of the dopants having the second conductivity type in the first sub-well region 108 may be different from a concentration of the dopants having the second conductivity type in the second sub-well region 109. Other configurations may be identical or similar to those discussed with reference to FIGS. 1A to 4.

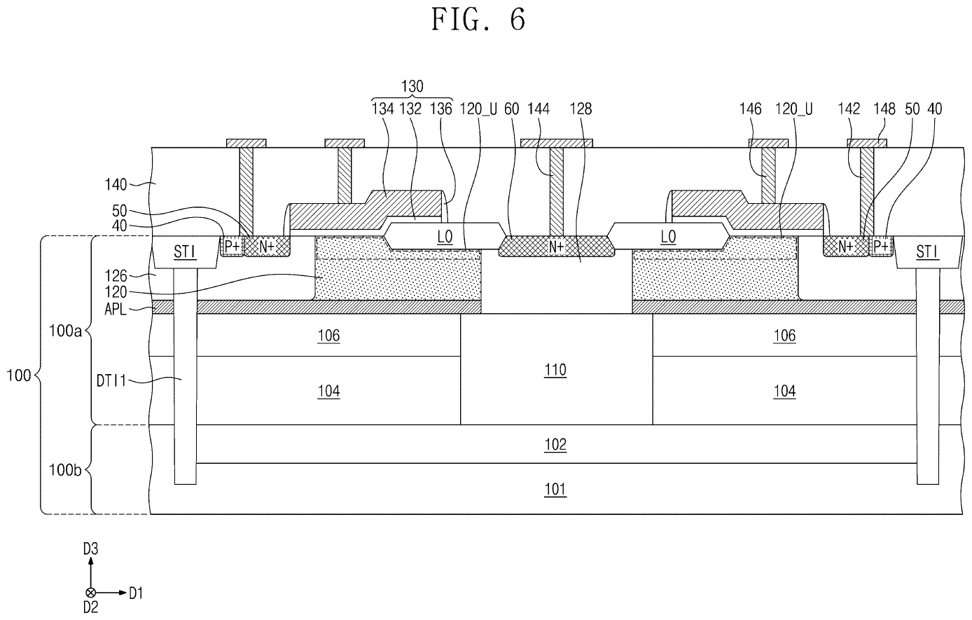

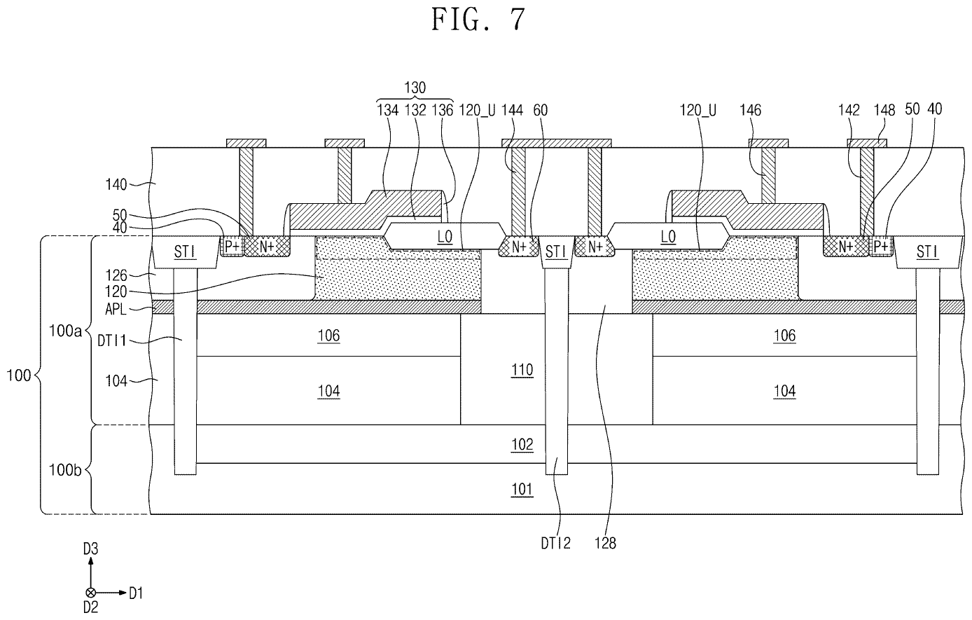

FIGS. 6 and 7 illustrate cross-sectional views showing semiconductor devices according to some example embodiments of the present inventive concepts.

Referring to FIG. 6, a first device isolation layer DTI1 may be disposed to penetrate a portion of the body region 126, the connection layer APL, the first deep well region 106, and a portion of the lower layer 101. The first device isolation layer DTI1 may have a single-layered or multi-layered structure of at least one selected from silicon oxide and silicon nitride. The buried layer 102 may be positioned between the first device isolation layers DTI1.

A first contact 142 may be connected to the first source region 50 and the second source region 40. A second contact 144 may be connected to the drain region 60. A third contact 146 may be connected to the gate structure 130. The first, second, and third contacts 142, 144, and 146 may be connected to their respective conductive patterns 148. The first contact 142 may be included in the source electrode ES of FIG. 1B, the second contact 144 may be included in the drain electrode ED of FIG. 1B, and the third contact 146 may be included in the gate electrode EG of FIG. 1B.

The first, second, and third contacts 142, 144, and 146 and the conductive patterns 148 may each include metal, such as copper, aluminum, tungsten, titanium, tantalum, titanium nitride, or tantalum nitride.

An interlayer dielectric layer 140 may cover the first, second, and third contacts 142, 144, and 146 and the semiconductor substrate 100. The interlayer dielectric layer 140 may have a single-layered or multi-layered structure of at least one selected from, for example, silicon oxide, silicon nitride, silicon oxynitride, SiCN, or porous dielectrics. Other configurations may be identical or similar to those discussed with reference to FIGS. 1A to 2I.

Referring to FIG. 7, a first device isolation layer DTI1 may be disposed to penetrate a portion of the body region 126, the connection layer APL, the first deep well region 106, and a portion of the lower layer 101. A second device isolation layer DTI2 may be disposed to penetrate the first shallow well region 128, the second deep well region 110, the buried layer 102, and a portion of the lower layer 101. The first deep well region 106 may be positioned between the first device isolation layer DTI1 and the second deep well region 110. Other configurations may be identical or similar to those discussed with reference to FIGS. 1A to 2I and 6.

In semiconductor devices according to some example embodiments of the present inventive concepts, a connection layer may be disposed on a lower portion of a drift region, and thus a breakdown voltage may be maintained and a reduced internal resistance may be provided between a drain and a source. For example, a resistance (Rsp: specific on resistance) when a current flows in a switched-on state may be reduced to cut power loss. Accordingly, the semiconductor device may have improved electrical properties.

Although some example embodiments of the present disclosure have been discussed with reference to accompanying figures, it will be understood that various changes in form and details may be made therein without departing from the spirit and scope of the present disclosure. It will be apparent to those skilled in the art that various substitution, modifications, and changes may be thereto without departing from the scope and spirit of the present disclosure.

What is claimed is:

1. A semiconductor device, comprising:
a semiconductor substrate comprising an upper area and a lower area, the lower area including a lower layer having a first conductivity type;
a first deep well region having the first conductivity type, the first deep well region being on the upper area;
a connection layer having the first conductivity type, the connection layer being on the first deep well region;
a body region having the first conductivity type and a first drift region having a second conductivity type different than the first conductivity type, the body region and the first drift region being side-by-side in a first direction on the connection layer;
a first source region having the second conductivity type, the first source region being on the body region;
a drain region having the second conductivity type, the drain region being on the upper area and being spaced apart from the first drift region in the first direction; and
a gate structure on the first drift region, the gate structure being adjacent to the first source region.

2. The semiconductor device of claim 1, further comprising:
a second deep well region having the second conductivity type, the second deep well region being side-by-side with the first deep well region in the first direction; and
a first shallow well region having the second conductivity type, the first shallow well region being on the second deep well region and being adjacent to lateral portions of the first drift region and the connection layer,
wherein the drain region is on an upper portion of the first shallow well region.

3. The semiconductor device of claim 2, wherein the first drift region and the connection layer extend to overlap the second deep well region.

4. The semiconductor device of claim 2, wherein the semiconductor substrate further comprises:
a buried layer having the second conductivity type, the buried layer being on the lower area,
wherein the buried layer contacts a bottom end of the second deep well region and is spaced apart from a bottom end of the first deep well region.

5. The semiconductor device of claim 2, further comprising a device isolation layer that penetrates the first shallow well region, the second deep well region, and a portion of the lower layer.

6. The semiconductor device of claim 2, further comprising a second drift region on the second deep well region, the second drift region covering a lower portion and a lateral portion of the first shallow well region, the second drift region being in contact with the lateral portions of the first drift region and the connection layer,
wherein, when viewed in the first direction, a first horizontal distance between the first shallow well region and the first deep well region is greater than a second horizontal distance between the first shallow well region and the first drift region.

7. The semiconductor device of claim 2, wherein the second deep well region comprises a first sub-well region, and a second sub-well region stacked on the first sub-well region.

8. The semiconductor device of claim 7, wherein
the first and second sub-well regions are doped with an n-type dopant, and
a concentration of the n-type dopant in the first sub-well region is different from a concentration of the n-type dopant in the second sub-well region.

9. The semiconductor device of claim 1, wherein a concentration of a dopant having the first conductivity type in the connection layer is different from a concentration of a dopant having the first conductivity type in the first deep well region.

10. The semiconductor device of claim 1, further comprising a device isolation layer that penetrates a portion of the body region, the connection layer, the first deep well region, and a portion of the lower layer.

11. The semiconductor device of claim 1, wherein
the first conductivity type is p-type, and
the second conductivity type is n-type.

12. The semiconductor device of claim 1, further comprising a local oxidation layer between the first drift region and a portion of the gate structure,
wherein a portion of the local oxidation layer is in the first drift region, and
wherein the local oxidation layer is between the drain region and the body region, and the local oxidation layer is spaced apart from the body region.

13. The semiconductor device of claim 12, wherein
the connection layer has a first thickness,
the first drift region has a second thickness from a bottom end of the first drift region to a bottom surface of the local oxidation layer, and
the second thickness is greater than the first thickness.

14. The semiconductor device of claim 1, wherein
the second conductivity type is n-type,
the first drift region is doped with an n-type dopant,
the first drift region comprises a first region adjacent to the gate structure, and
a concentration of the n-type dopant in the first drift region increases in a direction toward the first region from a bottom end of the first drift region.

15. The semiconductor device of claim 1, further comprising a second source region having the first conductivity type, the second source region being on the body region and being adjacent to the first source region.

16. The semiconductor device of claim 1, further comprising:
a first contact connected to the first source region;
a second contact connected to the drain region;
a third contact connected to the gate structure; and
an interlayer dielectric layer covering the first, second and third contacts and the semiconductor substrate.

17. The semiconductor device of claim 16, further comprising a second source region having the first conductivity type, the second source region being on the body region and being adjacent to the first source region,
wherein the first contact is connected to the second source region.

18. A semiconductor device, comprising:
a semiconductor substrate comprising an upper area and a lower area, the lower area including a lower layer having a first conductivity type;
a buried layer having a second conductivity type different than the first conductivity type, the buried layer being on the lower layer;
an epitaxial layer having the first conductivity type, the epitaxial layer being on the upper area;
a first deep well region having the first conductivity type, the first deep well region being on the epitaxial layer;
a second deep well region having the second conductivity type, the second deep well region being side-by-side with the first deep well region in a first direction, and the second deep well region having a bottom end in contact with the buried layer;
a connection layer having the first conductivity type, the connection layer being on the first deep well region;
a body region having the first conductivity type and a first drift region having the second conductivity type, the body region and the first drift region being side-by-side in the first direction on the connection layer;
a first source region having the second conductivity type, the first source region being on the body region;
a second drift region having the second conductivity type, the second drift region being on the second deep well region and contacting lateral portions of the first drift region and the connection layer;
a first shallow well region in the second drift region, the first shallow well region being spaced apart from the first drift region;
a drain region having the second conductivity type, the drain region being on the first shallow well region;
a gate structure on the first drift region, the gate structure being adjacent to the first source region; and
a local oxidation layer between the first drift region and a portion of the gate structure,
wherein
a portion of the local oxidation layer is in the first drift region,
the local oxidation layer is between the drain region and the body region, and the local oxidation layer is spaced apart from the body region,
the connection layer has a first thickness,
the first drift region has a second thickness from a bottom end of the first drift region to a bottom surface of the local oxidation layer, and
the second thickness is greater than the first thickness.

19. A semiconductor device, comprising:
a semiconductor substrate comprising an upper area and a lower area, the lower area including a lower layer having a first conductivity type;
a first deep well region having the first conductivity type and a second deep well region having a second conductivity type different than the first conductivity type, the first deep well region and the second deep well region being side-by-side in a first direction on the upper area;
a body region having the first conductivity type and a first drift region having the second conductivity type, the body region and the first drift region being side-by-side in the first direction on the first deep well region;
a first source region having the second conductivity type, the first source region being on the body region;
a gate structure on the first drift region, the gate structure being adjacent to the first source region;
a first shallow well region having the second conductivity type, the first shallow well region being on the second deep well region; and
a drain region having the second conductivity type, the drain region being on the first shallow well region and being spaced apart from the first drift region in the first direction,
wherein
the first drift region comprises a first region adjacent to the gate structure, and
a concentration of a dopant of the second conductivity type in the first drift region increases in a direction toward the first region from a bottom end of the first drift region.

20. The semiconductor device of claim 19, further comprising a connection layer having the first conductivity type, the connection layer being between the first deep well region and the body region and being between the first deep well region and the first drift region,
wherein the first drift region and the connection layer extend to contact a lateral portion of the first shallow well region.
